(19) United States
(12) Patent Application Publication
(10) Pub. No.: US 2011/0217816 A1
(43) Pub. Date: Sep. 8, 2011

(54) FIELD EFFECT TRANSISTOR AND METHOD FOR FABRICATING THE SAME

(75) Inventor: Keita MATSUDA, Yamanashi (JP)

(73) Assignee: EUDYNA DEVICES INC., Yamanashi (JP)

(21) Appl. No.: 13/110,230

(22) Filed: May 18, 2011

Related U.S. Application Data
(62) Division of application No. 12/179,896, filed on Jul. 25, 2008.

(30) Foreign Application Priority Data
Jul. 25, 2007 (JP) 2007-193550

(51) Int. Cl. H01L 21/335

(52) U.S. Cl. 438/172; 257/E21.403

(57) ABSTRACT

A field effect transistor includes: a nitride semiconductor layer having a channel layer; a gate electrode including a Schottky electrode that contacts the nitride semiconductor layer and includes a gallium doped zinc oxide

(GZO) layer annealed in an inactive gas atmosphere; and ohmic electrodes connecting with the channel layer.

### CROSS-REFERENCE TO RELATED APPLICATIONS

This application is a divisional of U.S. application Ser. No. 12/179,896, filed on Jul. 25, 2008, which in turn is based upon and claims the benefit of priority of the prior Japanese Patent Application No. 2007-193550, filed on Jul. 25, 2007, the entire contents of which are incorporated herein by reference.

### BACKGROUND OF THE INVENTION

1. Field of the Invention

The present invention relates to field effect transistors and methods for fabricating the same, and more particularly, to a field effect transistor having a Schottky junction of a nitride semiconductor layer and GZO layer and a method for fabricating such a transistor.

2. Description of the Related Art

A semiconductor device containing gallium nitride (GaN) is known as compound semiconductor containing nitride. The GaN semiconductor device I used as a power device capable of outputting high power at high frequencies. Particularly, there has been considerable activity in the development of field effect transistors (FETs) capable of suitably amplifying signals in high-frequency bands such as microwaves, quasi-millimeter waves or millimeter waves. A typical example of such FETs is a high electron mobility transistor (HEMT).

The gate electrode of the FET and the anode electrode of a Schottky diode are formed by electrodes having Schottky junctions (Schottky electrodes). The Schottky electrodes are required to have reduced leakage current. Preferably, the leakage current is reduced by increasing the Schottky barrier height. The Schottky electrode with nitride semiconductor may be an electrode having a metal layer having a large work function that contacts a nitride semiconductor layer. Such a metal layer may be formed by Ti(titanium)/Pt(platinum)/Au(gold), Ni(nickel)/Au or Pt/Au in which Au is the uppermost layer. For example, Japanese Patent Application Publication No. 2006-339453 discloses Ni/Au is used to form the Schottky electrode. The nitride semiconductor may be GaN, AlN (aluminum nitride), InN (indium nitride), AlGaN (a mixed crystal of GaN and AlN), InGaN (a mixed crystal of GaN and InN), or AlInGaN (a mixed crystal of GaN, AlN and InN).

However, the conventional Schottky junction of the nitride semiconductor does not have a greatly increased Schottky barrier height even by using metal having a large work function. This may be because of pinning level on the surface of the nitride semiconductor. It is thus difficult to reduce the leakage current. Further, impurities remain at the interface between the nitride semiconductor and the Schottky electrode, and may increase the leakage current when the interface is reverse-biased.

### SUMMARY OF THE INVENTION

The present invention has been made in view of the above-mentioned circumstances and aims at restraining the leakage current that flows through the Schottky junction.

According to an aspect of the present invention, there is provided a field effect transistor including: a nitride semiconductor layer having a channel layer; a gate electrode including a Schottky electrode that contacts the nitride semiconductor layer and includes a gallium doped zinc oxide (GZO) layer annealed in an inactive gas atmosphere; and ohmic electrodes connecting with the channel layer. With this structure, reverse leakage current flowing through the Schottky junction can be restrained and the ideality factor of the forward current can become closer to 1.

The field effect transistor may be configured so that the nitride semiconductor layer includes a layer made of AlGaN, InAlN, InAlGaN or GaN. The field effect transistor may be configured so that the Schottky electrode includes an Au electrode layer provided on a barrier layer on the GZO layer. Thus, the Schottky electrode has a reduced resistance. The field effect transistor may be configured so that the barrier layer is made of nickel. The field effect transistor may be configured so that the inactive gas is one of nitrogen, neon, helium and argon gasses.

According to another aspect of the present invention, there is provided a method for fabricating a field effect transistor, including: forming a Schottky electrode including a gallium doped zinc oxide (GZO) layer that contacts a nitride semiconductor layer having a channel layer; forming ohmic electrodes connecting with the channel layer; and performing annealing in an inactive gas atmosphere.

The method may be configured so that forming the Schottky electrode includes: forming the GZO layer on the nitride semiconductor layer; and removing the GZO layer except an area in which the Schottky electrode should be formed. It is thus possible to restrain a defective layer from being formed in the nitride semiconductor layer between the Schottky electrode and an ohmic electrode. The method may be configured so that forming the Schottky electrode uses one of a vacuum evaporation method and a sputtering method, and includes forming a layer that includes the GZO layer.

### BRIEF DESCRIPTION OF THE DRAWINGS

FIGS. 1A through 1D are respectively cross-sectional views of a wafer used to fabricate a sample FET in accordance with a first embodiment;

FIGS. 2A and 2B are respectively graphs of gate I-V characteristics of a comparative example after annealing

FIGS. 3A and 3B are respectively graphs of gate I-V characteristics of a first embodiment prior to annealing;

FIGS. 4A and 4B are respectively graphs of gate I-V characteristics of the first embodiment after annealing;

FIG. 5 shows a presumed factor that causes leakage current;

FIGS. 6A and 6B are respectively energy band diagrams observed below the gate electrode; and

FIGS. 7A through 7D are respectively cross-sectional views of a wafer used to an FET in accordance with a second embodiment.

### DETAILED DESCRIPTION

A description will now be given of embodiments of the present invention with reference to the accompanying drawings.

### First Embodiment

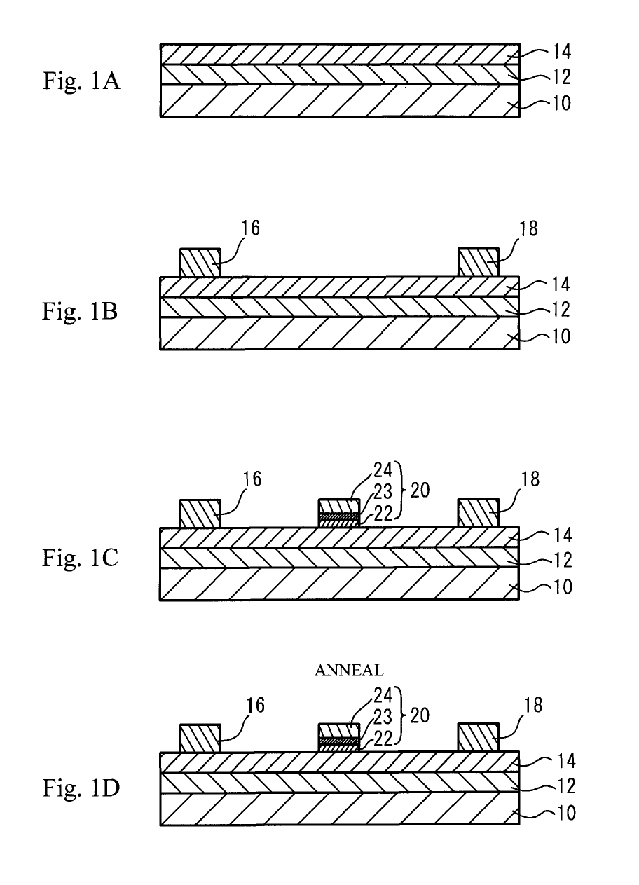

FIGS. 1A through 1D are respectively cross-sectional views that illustrate a method for fabricating an FET. The inventors actually fabricated the FET as follows. Referring to FIG. 1A, a nitride semiconductor layer was formed on a sapphire substrate 10 by MOCVD (Metal Organic Chemical Vapor Deposition). The nitride semiconductor layer had an undoped GaN electron conduction layer 12 having a thickness of 2 μm, and an undoped Al_{0.25}Ga_{0.75}N electron supply layer 14 that is provided on the layer 12 and is 25 nm thick. Referring to FIG. 1B, a device isolation region was formed by etching. A source electrode 16 and a drain electrode 18 were formed by an evaporation method and a liftoff method. The electrodes 16 and 18 formed a pair of ohmic electrodes electrically connected to a two-dimensional electron gas in the electron conduction layer 12 (channel layer), and had a Ti/Al layer structure. Referring to FIG. 1C, a GZO layer 22 having a thickness of approximately 50 nm was formed on the electron supply layer 14 by a vacuum evaporation method and liftoff method. The material evaporated in the vacuum evaporation in an experimental fabrication process was ZnO (zinc oxide) : Ga₂O₃ (gallium oxide) equal to 94.5:5.5 weight % evaporated by EB (Electron Beam). A barrier layer 23 that was made of Ni and was approximately 80 nm thick was formed on the GZO layer 22 by the vacuum evaporation method and the liftoff method. An Au electrode layer 24 having a thickness of about 100 nm was formed on the barrier layer 23 by the vacuum evaporation method and the liftoff method.

Thus, a gate electrode 20 made of the GZO layer 22, the barrier layer 23 and the Au electrode layer 24 was formed. Referring to FIG. 1D, the wafer was annealed in a nitrogen atmosphere at an annealing temperature of 350° C. for 30 minutes.

As a comparative example, the inventors fabricated a sample in which the gate electrode 20 did not have the GZO layer 22, so that Ni/Au was directly formed on the electron supply layer 14. The first embodiment and the comparative example were formed on the same wafer, which was divided into parts before the gate electrode 20 was formed in FIG. 1C. As has been described, the first embodiment has the gate electrode made up of the GZO layer 22, the barrier layer 23 and the Au electrode layer 24. In contrast, the comparative example, only the barrier layer 23 and the Au electrode layer 24 were formed on the electron supply layer 14 in that order. The subsequent process in the comparative example was the same as that in the first embodiment.

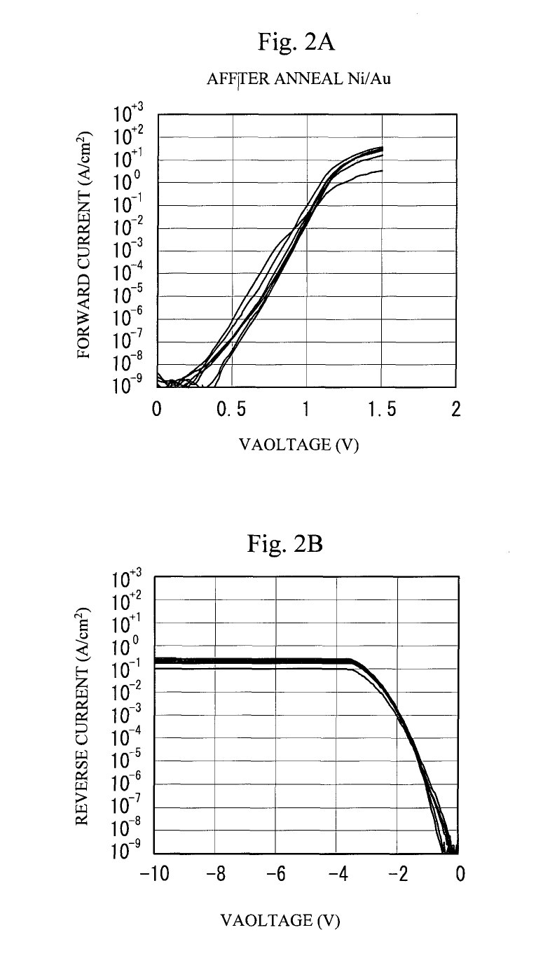

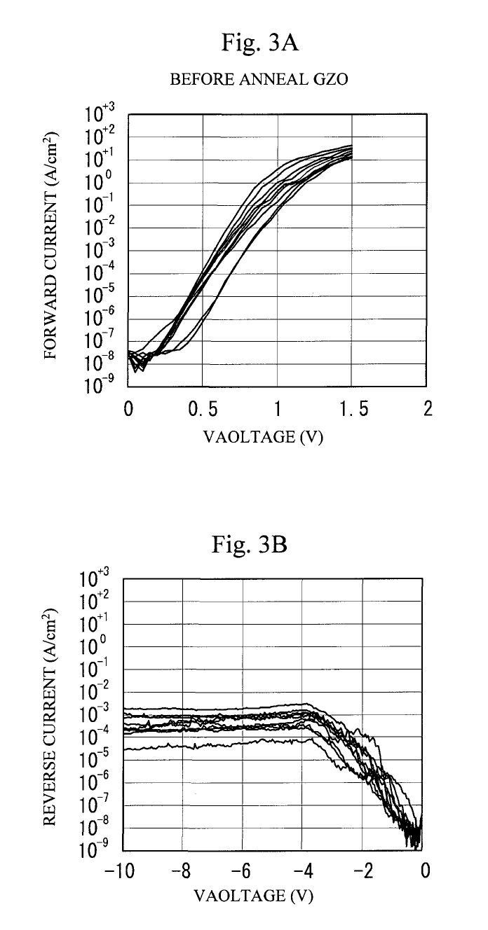

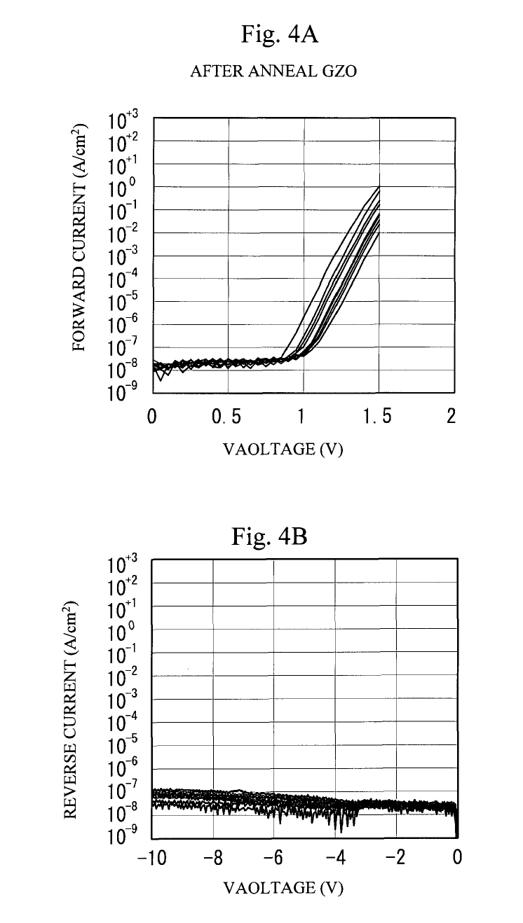

FIG. 2A is a graph of a gate forward-biased characteristic of the first comparative example observed after annealing at 350° C. for 30 minutes, and FIG. 2B is a graph of a gate reverse-biased characteristic thereof. The vertical axes of the graphs denote current per unit area (A/cm²). FIGS. 3A and 3B are respectively graphs of gate forward-biased and reverse-biased characteristics of the first embodiment observed prior to annealing. FIGS. 4A and 4B are respectively graphs of gate forward-biased and reverse-biased characteristics of the first embodiment after annealing at 350° C. for 30 minutes. A plurality of curved lines in the graphs are characteristics of different FETs formed at different positions on the wafer.

It can be seen from FIGS. 2A, 3A and 4A that the forward currents in the comparative example after annealing are approximately equal to those of the first embodiment prior to annealing. In these characteristics, the forward currents start to flow at a low voltage. In contrast, the forward currents of the first embodiment after annealing are reduced by a few digits at low voltages, and the forward currents start to flow at a voltage equal to or greater than 0.5 V. It is conceivable that the FETs of the first embodiment after annealing have a higher Schottky barrier than those of the FETs of the comparative example after annealing and those of the FETs of the first embodiment prior to annealing. The FETs of the first embodiment after annealing have an increased slope of the forward current and the ideality factor of the Schottky junction becomes closer to 1.

It can be seen from FIGS. 2B, 3B and 4B that the reverse currents of the FETs of the first embodiment are two orders of magnitude smaller than those of the comparative example. The reverse currents of the FETS of the first embodiment after annealing are further reduced by four digits or more as compared to those before annealing. It is to be noted that data for currents equal to 10⁻⁷ A/cm² or smaller exceed beyond the limitation in measurement and are not measured accurately. It can be seen from the above that the first embodiment has an extremely reduced leakage current by annealing, which may heighten the Schottky barrier.

The reverse currents of the FETs of the first embodiment (see FIG. 3B) are smaller than those of the comparative example after annealing (see FIG. 2B). However, such reverse currents of the FETs are not satisfactory in practice. The forward currents of the FETs of the first embodiment prior to annealing (see FIG. 3A) are approximately equal to those of the comparative example after annealing (see FIG. 2A). It can be seen from the above that even the first embodiment does not have satisfactory gate current—voltage characteristics unless annealing is applied thereto. In contrast, as shown in FIGS. 4A and 4B, when annealing is employed in the first embodiment, the leakage currents in the gate forward and reverse directions can be restrained, so that almost ideal gate current-voltage characteristics can be obtained.

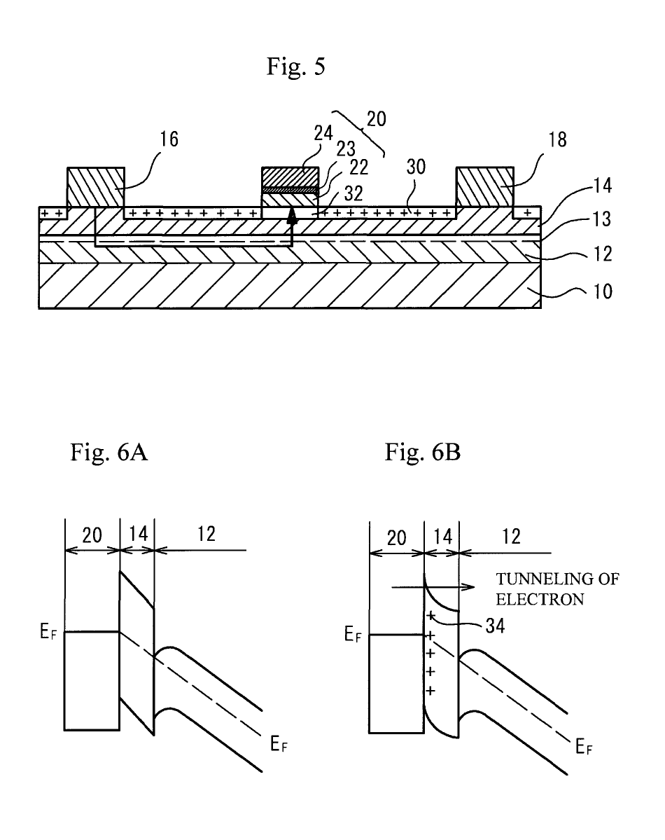

As described above, the Schottky characteristics can be greatly improved by using GZO to form the metal layer that contacts the semiconductor layer of the Schottky electrode. The mechanism for improvements may be conceived as follows. Referring to FIG. 5, a defective layer 30 is formed on the surface of the AlGaN electron supply layer 14. The reverse current flows from the source electrode 16 to the gate electrode 20 via the two-dimensional gas (2DEG), as indicated by an arrow in FIG. 5. FIGS. 6A and 6B are respectively energy band diagrams observed below the gate electrode 20 when a reverse voltage is applied. Ideally, as shown in FIG. 6A, the electron supply layer 14 functions as a barrier between the gate electrode 20 and the electron conduction layer 12, and small leakage current should flows. However, if the defective layer 30 is formed on the surface of the electron supply layer 14, as shown in FIG. 6B, a level 34 is formed on the surface of the electron supply layer 14. Thus, the band is bent, and the band width is reduced. Thus, the electrons tunnels the barrier and increases the leakage current.

The defective layer 30 may be formed as follows. The surface of the electron supply layer 14 is oxidized, and an oxide layer is thus formed thereon. It is conceived that the GZO layer 22 of the first embodiment applies capturing of the oxide layer formed on the surface of the electron supply layer 14, and defects due to oxygen in the defective layer disappear. There may be another factor that causes the defective layer 30. More particularly, nitrogen in the proximity of the surface of the electron supply layer 14 may be deficient. The GZO layer 22 of the first embodiment restrain nitrogen from coming out of the surface of the electron supply layer 14, and thus prevents the defective layer 30 from being formed. As described above, the defective layer 30 may be due to the oxide layer or nitrogen deficiency or both.

According to the first embodiment, the layer of the gate electrode 20 that contacts the electron supply layer 14 is the GZO layer 22 and is annealed. It is thus conceived that the level 34 due to the defective layer 30 disappears and the forward and reverse leakage currents are reduced.

### Second Embodiment

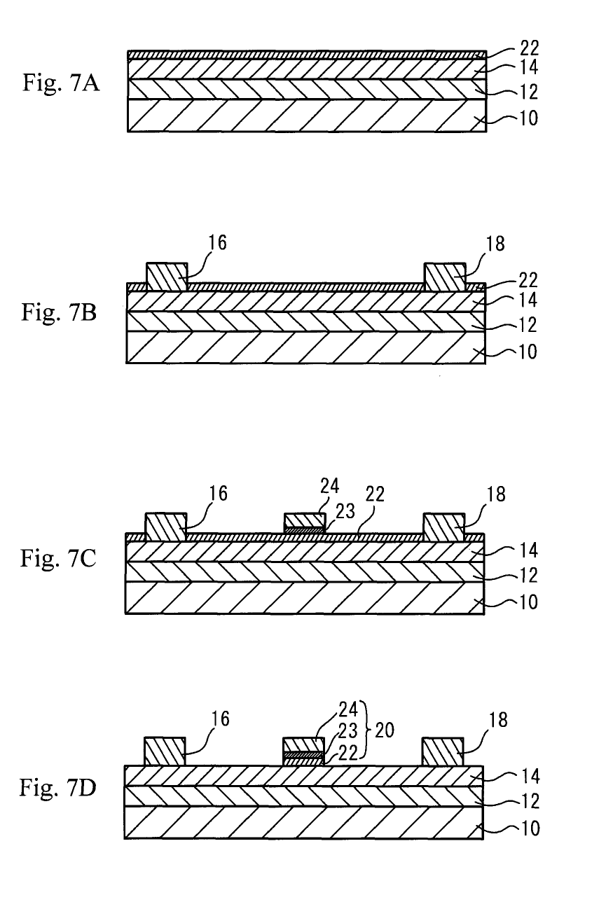

A second embodiment has the gate electrode 20 formed by a different method. FIGS. 7A through 7D are respectively cross-sectional views that show a method for fabricating an FET according to the second embodiment. Referring to FIG. 7A, the GZO layer 22 is formed on the entire surface of the AlGaN electron supply layer 14.

Referring to FIG. 7B, a part of the GZO layer 22 is removed to expose the electron supply layer 14. The source electrode 16 and the drain electrode 18 are formed on the exposed surface portions of the electron supply layer 14. Referring to FIG. 7C, the barrier layer 23 is formed on the GZO layer 22 by forming a Ni layer having a thickness of 80 nm and an Au electrode layer 24 having a thickness of 100 nm. Then, the wafer is annealed in the nitrogen atmosphere. The GZO layer 22 restrains the defective layer from being formed on the surface of the electron supply layer 14. Referring to FIG. 7D, the GZO layer 22 is removed except a portion that should be a part of the gate electrode 20. Thus, the gate electrode 20 is formed by the above-mentioned process, and the FET of the second embodiment is completed. The second embodiment is capable of restraining a defective layer of the electron supply layer 14 between the source electrode 16 and the drain electrode 18 (that is, the Schottky electrode and the ohmic electrode).

The first and second embodiments employ the electron supply layer 14 made of AlGaN. The surface of the nitride semiconductor layer is easily oxidized and nitrogen is deficient therefrom. The Schottky characteristics can be improved by providing, as the Schottky electrode 20, the GZO layer 22 in contact with the nitride semiconductor layer.

Particularly, AlGaN, InAlN, InAlGaN or GaN is often used to form a semiconductor layer for the Schottky junction. It is thus preferable that the nitride semiconductor layer contains a layer that is in contact with the GZO layer 22 and is made of AlGaN, InAlN, InAlGaN or GaN. The GZO layer 22 can improve the Schottky characteristics. Particularly, AlGaN is easily oxidized as compared to the other materials. Thus, the GZO layer 22 is more preferably employed to form the Schottky electrode on the AlGaN layer.

The Schottky electrode may include only the GZO layer 22. In order to reduce the contact resistance, preferably, the barrier layer 23 is provided on the GZO layer 22, and the Au electrode layer 24 is provided on the barrier layer 23. The barrier layer 23 is not limited to Ni, but may be made of any material that functions as a barrier between the GZO layer 22 and the Au electrode layer 24.

The GZO layer 22 may be formed by not only the vacuum evaporation method, but also sputtering, MOVPE (Metal Organic Vapor Phase Epitaxy), MBE (Molecular Beam Epitaxy), MOCVD, CVD or PXD (Pulsed eXcitation Deposition).

In order to prevent the surface of the nitride semiconductor layer from being oxidized, it is preferable that annealing is carried out in an inactive gas atmosphere in the absence of oxygen. The inactive gas may be N₂, Ne (neon), He (helium) or Ar (argon). Further, in order to restrain nitrogen from being removed during annealing, the inactive gas is preferably a nitrogen gas. In order to obtain excellent Schottky characteristics, annealing is performed in a temperature range of 250° C. to 550° C.

The above-mentioned FETs are of planar type in which the source electrode and the drain electrode (a pair of ohmic electrodes) are formed on the nitride semiconductor layer. The present invention is not limited to the planar type but includes a vertical type in which the source electrode is provided on the nitride semiconductor electrode and the drain electrode is provided below the nitride semiconductor electrode. The present invention includes not only the FETs but also other types of semiconductor devices that employ the Schottky junctions such as Schottky diodes.

The present invention is not limited to the specifically disclosed embodiments, but include other embodiments and variations without departing from the scope of the present invention.

The present application is based on Japanese Patent Application No. 2007-193550 filed Jul. 25, 2007, the entire disclosure of which is hereby incorporated by reference.

What is claimed is:

1. A method for fabricating a field effect transistor, comprising:
forming a nitride semiconductor layer on a channel layer made of nitride semiconductor;
forming an ohmic electrode electrically connected to the channel layer;
forming a Schottky electrode including a gallium doped zinc oxide (GZO) layer that contacts the nitride semiconductor layer, after forming the ohmic electrodes; and
performing annealing of the Schottky electrode in an inactive gas atmosphere, after forming Schottky electrode.

2. The method as claimed in claim 1, wherein the nitride semiconductor layer includes a layer made of AlGaN, InAlN, InAlGaN or GaN.

3. The method as claimed in claim 1, further comprising:
forming a barrier layer on the Schottky electrode; and
forming an Au electrode layer on the barrier layer.

4. The method as claimed in claim 1, wherein the inactive gas is one of nitrogen, neon, helium and argon gasses.

5. The method as claimed in claim 1, wherein forming the Schottky electrode includes:
forming the GZO layer on the nitride semiconductor layer; and
removing the GZO layer except an area in which the Schottky electrode should be formed after annealing.

6. The method as claimed in claim 1, wherein forming the GZO uses one of a vacuum evaporation method and a sputtering method.

7. The method as claimed in claim 1, wherein the channel layer includes a layer made of GaN, AlN, InGaN, InAlGaN or InN.

8. The method as claimed in claim 1, wherein the annealing of the Schottky electrode is performed in a temperature range of 250° C. to 440° C.

9. The method as claimed in claim 1, wherein the barrier layer is made of Ni.
